(19) United States
(12) Patent Application Publication
(10) Pub. No.: US 2025/0374738 A1
(43) Pub. Date: Dec. 4, 2025

(54) DISPLAY DEVICE AND METHOD OF FABRICATING THE SAME

(71) Applicant: Samsung Display Co., LTD., Yongin-si (KR)

(72) Inventors: Sung Hwan KIM, Yongin-si (KR); Min Chul SHIN, Yongin-si (KR); Ji Youn SEO, Yongin-si (KR); Hui Won YANG, Yongin-si (KR)

(73) Assignee: Samsung Display Co., LTD., Yongin-si (KR)

(21) Appl. No.: 19/178,072

(22) Filed: Apr. 14, 2025

(30) Foreign Application Priority Data
May 29, 2024 (KR) 10-2024-0069830

(51) Int. Cl. H10H 29/855; H10H 29/01

(52) U.S. Cl. CPC H10H 29/8552; H10H 29/012; H10H 29/0363

(57) ABSTRACT

A method of fabricating a display device includes: providing a substrate; forming an electrode layer on the substrate; bonding a light emitting element to the electrode layer; forming a light blocking layer to cover at least a portion of the light emitting element; ashing the light blocking layer; and forming a color filter on the light emitting element.

### CROSS-REFERENCE TO RELATED APPLICATION

This application claims priority to and the benefits of Korean patent application number 10-2024-0069830 under 35 U.S.C. § 119, filed on May 29, 2024 in the Korean Intellectual Property Office, the entire disclosure of which is incorporated herein by reference.

### BACKGROUND

### 1. Technical Field

Various embodiments of the disclosure relate to a display device and a method of manufacturing the display device.

### 2. Description of Related Art

With the advancement of information technology, the importance of a display device, which functions as a connection medium between a user and information, has been emphasized. Due to the importance of the display device, the utilization of various display devices, such as liquid crystal displays, organic light emitting displays, and inorganic light emitting displays, has increased. Recently, research on micro-LEDs, which offer faster response times and higher luminance compared to existing LEDs, has been actively conducted.

### SUMMARY

Various embodiments are directed to a method of fabricating a display device that increases light output efficiency of a light emitting element.

Various embodiments are directed to a display device fabricated using the display device fabrication method.

An embodiment may provide a method of fabricating a display device, including: providing a substrate; forming an electrode layer on the substrate; bonding a light emitting element to the electrode layer; forming a light blocking layer to cover at least a portion of the light emitting element; ashing the light blocking layer; and forming a color filter on the light emitting element.

In an embodiment, the light blocking layer may cover an entirety of the light emitting element.

In an embodiment, the light blocking layer may include an opening through which a portion of the light emitting element is exposed.

In an embodiment, the light blocking layer may be ashed such that an upper surface of the light blocking layer is lower than an upper surface of the light emitting element.

In an embodiment, the electrode layer may include a first electrode and a second electrode that are electrically connected to the light emitting element. The first electrode and the second electrode may be spaced apart from each other.

In an embodiment, the light blocking layer may surround the light emitting element.

An embodiment may provide a method of fabricating a display device, including: providing a substrate; forming a first electrode layer on the substrate; bonding a light emitting element to the first electrode layer; forming a second electrode layer on the light emitting element; forming a light blocking layer to cover the second electrode layer; ashing the light blocking layer; and forming a color filter on the light emitting element.

In an embodiment, the method may further include forming an overcoat layer on the first electrode layer. The second electrode layer may cover the overcoat layer and the light emitting element.

In an embodiment, the light blocking layer may be ashed such that an upper surface of the light blocking layer is lower than an upper surface of a portion of the second electrode layer that overlaps the light emitting element.

In an embodiment, the light blocking layer may surround the light emitting element.

An embodiment may provide a display device, including: a substrate; an insulating layer disposed on the substrate; an electrode layer disposed on the insulating layer; a light emitting element disposed on the electrode layer; a light blocking layer disposed on the electrode layer; and a color filter disposed on the light emitting element. An upper surface of the light blocking layer may be lower than an upper surface of the light emitting element.

In an embodiment, the electrode layer may include a first electrode and a second electrode that are electrically connected to the light emitting element. The first electrode and the second electrode may be spaced apart from each other.

In an embodiment, the light blocking layer may be disposed under the light emitting element.

In an embodiment, the light blocking layer may surround the light emitting element.

### BRIEF DESCRIPTION OF THE DRAWINGS

The above and other aspects, features, and advantages of embodiments of the disclosure will be more apparent from the following description taken in conjunction with the accompanying drawings, in which:

FIG. 1 is a schematic block diagram illustrating an embodiment of a display device.

FIG. 2 is a schematic block diagram illustrating an embodiment of a sub-pixel of FIG. 1.

FIG. 3 is a schematic plan view illustrating an embodiment of a display panel of FIG. 1.

FIG. 4 is a schematic sectional view illustrating an embodiment of the display panel of FIG. 3.

FIG. 5 is a schematic sectional view illustrating another embodiment of the display panel of FIG. 3.

FIG. 6 is a schematic plan view illustrating an embodiment of a pixel of FIG. 3.

FIG. 7 is a schematic sectional view taken along line I-I′ of FIG. 6.

FIG. 8 is a schematic sectional view taken along line II-II′ of FIG. 6.

FIG. 9 is a schematic plan view illustrating an embodiment of light emitting elements and a light blocking layer in a pixel of FIG. 3.

FIG. 10 is a schematic flowchart illustrating a method of fabricating the display device in accordance with embodiments.

FIG. 11 is a schematic diagram for describing steps S100 and S200 of FIG. 10.

FIG. 12 is a schematic diagram for describing step S300 of FIG. 10.

FIG. 13 is a schematic diagram for describing step S400 of FIG. 10.

FIG. 14 is a schematic diagram for describing step S500 of FIG. 10.

FIG. 15 is a schematic diagram for describing step S600 of FIG. 10.

FIGS. 16 to 18 are schematic diagrams for describing another embodiment of steps S400 to S600 of FIG. 10.

FIG. 19 is a schematic plan view illustrating another embodiment of a pixel of the display device.

FIG. 20 is a schematic sectional view taken along line X-X′ of FIG. 19.

FIG. 21 is a schematic plan view illustrating another embodiment of light emitting elements and a light blocking layer in a pixel of FIG. 3.

FIG. 22 is a schematic flowchart illustrating a method of fabricating the display device.

FIG. 23 is a schematic diagram for describing steps S110 and S210 of FIG. 22.

FIG. 24 is a schematic diagram for describing step S310 of FIG. 22.

FIG. 25 is a schematic diagram for describing step S410 of FIG. 22.

FIG. 26 is a schematic diagram for describing step S510 of FIG. 22.

FIG. 27 is a schematic diagram for describing step S610 of FIG. 22.

FIG. 28 is a schematic diagram for describing step S710 of FIG. 22.

FIG. 29 is a schematic block diagram illustrating an embodiment of a display system.

FIGS. 30 to 33 are schematic perspective views illustrating application examples of the display system of FIG. 29.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art. Various embodiments do not have to be exclusive nor limit the disclosure. For example, specific shapes, configurations, and characteristics of an embodiment may be used or implemented in another embodiment.

In the drawings, sizes, thicknesses, ratios, and dimensions of the elements may be exaggerated for ease of description and for clarity. Like reference numbers and/or reference characters refer to like elements throughout.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

In the case where an element, such as a layer, a region, a portion, or the like, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

As used herein, the singular forms “a,” “an,” and “the” are intended to include the plural forms as well, unless the context clearly indicates otherwise.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

It will be understood that, although the terms “first,” “second,” etc. may be used herein to describe various elements, these elements should not be limited by these terms. These terms are only used to distinguish one element from another. For example, a first element may be referred to as a second element, and similarly, a second element may be referred to as a first element without departing from the scope of the disclosure.

Spatially relative terms, such as “beneath,” “below,” “under,” “lower,” “on,” “above,” “upper,” “over,” “higher,” “side” (e.g., as in “sidewall”), and the like, may be used herein for descriptive purposes, and, thereby, to describe one element or feature's relationship to another element(s) or feature(s), as illustrated in the drawings. Spatially relative terms are intended to encompass different orientations of an apparatus in use, operation, and/or manufacture in addition to the orientation depicted in the drawings. For example, if the device in the drawings is turned over, elements described as “below” or “beneath” other elements or features would then be oriented “above” the other elements or features. Thus, the term “below” can encompass both an orientation of above and below. Furthermore, the device may be otherwise oriented (e.g., rotated 90 degrees or at other orientations), and, as such, the spatially relative descriptors used herein should interpreted accordingly.

The phrase “in a plan view” means viewing the object from the top, and the phrase “in a schematic cross-sectional view” means viewing a cross-section of which the object is vertically cut from the side. Hence, the expression “in a plan view” used herein may mean that an object is viewed in the third z direction from the top. The phrase “in a schematic cross-sectional view” means viewing a cross-section in the first x direction or the second y direction of which the object is vertically cut from the side. The third z direction also can be referred to as a “thickness direction.”

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments may be described and illustrated in the accompanying drawings in terms of functional blocks, units, and/or modules.

Those skilled in the art will appreciate that these blocks, units, and/or modules are physically implemented by electronic (or optical) circuits, such as logic circuits, discrete components, microprocessors, hard-wired circuits, memory elements, wiring connections, and the like, which are formed using semiconductor-based fabrication techniques or other manufacturing technologies.

In the case of the blocks, units, and/or modules being implemented by microprocessors or other similar hardware, they may be programmed and controlled using software (for example, microcode) to perform various functions discussed herein and may optionally be driven by firmware and/or software.

It is also contemplated that each block, unit, and/or module may be implemented by dedicated hardware, or as a combination of dedicated hardware to perform some functions and a processor (for example, one or more programmed microprocessors and associated circuitry) to perform other functions.

Each block, unit, and/or module of embodiments may be physically separated into two or more interacting and discrete blocks, units, and/or modules without departing from the scope of the disclosure.

Further, the blocks, units, and/or modules of embodiments may be physically combined into more complex blocks, units, and/or modules without departing from the scope of the disclosure.

Hereinafter, a display device and a method of manufacturing the display device according to embodiments of the disclosure will be described in more detail with reference to the accompanying drawings.

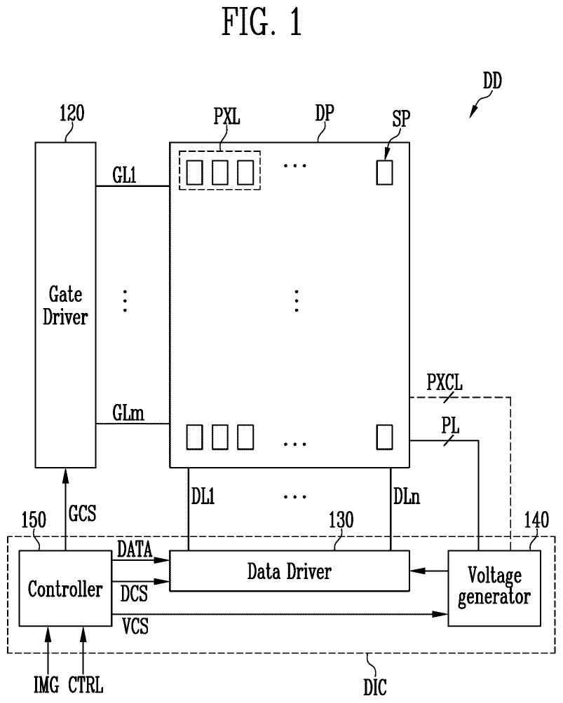

FIG. 1 is a schematic block diagram illustrating an embodiment of a display device DD.

Referring to FIG. 1, the display device DD may include a display panel DP, a gate driver 120, a data driver 130, a voltage generator 140, and a controller 150.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

The sub-pixels SP may generate light in two or more colors. For example, each of the sub-pixels SP may generate light in a color such as red, green, blue, cyan, magenta, or yellow.

Two or more sub-pixels SP may form a pixel (e.g., single pixel) PXL. For example, the pixel PXL may include three sub-pixels, as illustrated in FIG. 1. As such, the pixel PXL may emit light of various colors and various luminances depending on the combination of light emitted from the sub-pixels included therein.

The gate driver 120 may be connected to sub-pixels SP arranged in a row direction through first to m-th gate lines GL1 to GLm. The gate driver 120 may output gate signals to the first to m-th gate lines GL1 to GLm in response to a gate control signal GCS. In embodiments, the gate control signal GCS may include a start signal instructing the start of each frame, a horizontal synchronization signal, and the like.

The gate driver 120 may be disposed on one side of the display panel DP. However, embodiments are not limited to this example. For example, the gate driver 120 may be divided into two or more drivers that are physically and/or logically distinct. The drivers may be disposed on a first side of the display panel DP and a second side of the display panel DP opposite the first side. Thus, the gate driver 120 may be disposed around the display panel DP in various configurations depending on the embodiments.

The data driver 130 may be connected to sub-pixels SP arranged in a column direction through the first to n-th data lines DL1 to DLn. The data driver 130 may receive image data DATA and a data control signal DCS from the controller 150. The data driver 130 may operate in response to the data control signal DCS. In embodiments, the data control signal DCS may include a source start signal, a source shift clock, a source output enable signal, and the like.

The data driver 130 may receive voltages from the voltage generator 140. The data driver 130 may use the received voltages to apply data signals having grayscale voltages corresponding to the image data DATA to the first to n-th data lines DL1 to DLn. In the case where a gate signal is applied to each of the first to m-th gate lines GL1 to GLm, data signals corresponding to the image data DATA may be applied to the data lines DL1 to DLn. As a result, the sub-pixels SP may generate light corresponding to the data signals, and the display panel DP may display an image.

In embodiments, the gate driver 120 and the data driver 130 may include complementary metal-oxide semiconductor (CMOS) circuit elements.

The voltage generator 140 may operate in response to a voltage control signal VCS provided from the controller 150. The voltage generator 140 may generate multiple voltages and provide the generated voltages to components of the display device DD such as the gate driver 120, the data driver 130, and the controller 150. The voltage generator 140 may receive an input voltage from an external device of the display device DD and generate multiple voltages by regulating the received voltage.

The voltage generator 140 may generate a first power voltage and a second power voltage. The generated first and second power voltages may be provided to the sub-pixels SP through power lines PL. In other embodiments, at least one of the first and second power voltages may be provided from an external device to the display device DD.

The voltage generator 140 may provide various voltages and/or signals. For example, the voltage generator 140 may provide one or more initialization voltages to the sub-pixels SP. For example, in case that a sensing operation is performed for sensing electrical characteristics of transistors and/or light emitting elements in the sub-pixels SP, a desired reference voltage may be applied to each of the first to n-th data lines DL1 to DLn. The voltage generator 140 may generate and transmit the reference voltage to the data driver 130. For example, during a display operation for displaying an image on the display panel DP, common pixel control signals may be applied to the sub-pixels SP, and the voltage generator 140 may generate the pixel control signals. In embodiments, the voltage generator 140 may provide pixel control signals to the sub-pixels SP through pixel control lines PXCL. Although FIG. 1 illustrates the case where the pixel control lines PXCL are connected between the voltage generator 140 to the display panel DP, other embodiments are possible. For example, the pixel control lines PXCL may be connected between the gate driver 120 and the display panel DP. The pixel control signals may be transmitted from the voltage generator 140 to the pixel control lines PXCL through the gate driver 120.

The controller 150 may control overall operations of the display device DD. The controller 150 may receive input image data IMG and corresponding control signal CTRL from an external device. The controller 150 may provide a gate control signal GCS, a data control signal DCS, or a voltage control signal VCS, depending on the control signal CTRL.

The controller 150 may convert the input image data IMG to be suitable for the display device DD or the display panel DP and then output image data DATA. In embodiments, the controller 150 may align the input image data IMG to be suitable for the sub-pixels SP on a row basis and then output the image data DATA.

Two or more components of the data driver 130, the voltage generator 140, or the controller 150 may be mounted on a single integrated circuit. As illustrated in FIG. 1, the data driver 130, the voltage generator 140, and the controller 150 may be included in a driver integrated circuit DIC. The data driver 130, the voltage generator 140, and the controller 150 may be functionally separated components in the single driver integrated circuit DIC. In other embodiments, at least one of the data driver 130, the voltage generator 140, and the controller 150 may be provided as a separate component from the driver integrated circuit DIC.

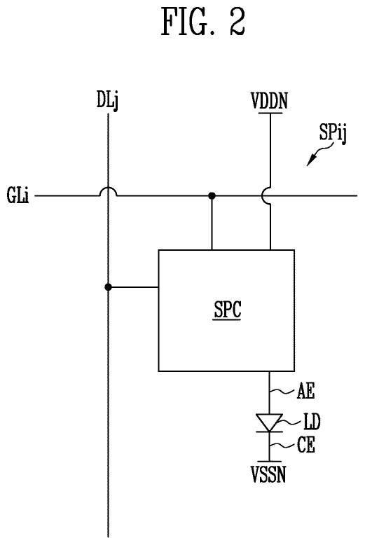

FIG. 2 is a schematic block diagram illustrating an embodiment of a sub-pixel SP from FIG. 1. In FIG. 2, a sub-pixel SPij is illustrated, disposed in an i-th row (where i is an integer greater than or equal to 1 and less than or equal to m) and a j-th column (where j is an integer greater than or equal to 1 and less than or equal to n) among the sub-pixels SP of FIG. 1.

Referring to FIG. 2, the sub-pixel SPij may include a sub-pixel circuit SPC and a light emitting element LD.

The light emitting element LD is connected between a first power voltage node VDDN and a second power voltage node VSSN. The first power voltage node VDDN may be connected to one of the power lines PL of FIG. 1 to receive a first power voltage. The second power voltage node VSSN may be connected to another power line PL of FIG. 1 to receive a second power voltage. The first power voltage may have a higher voltage level than the second power voltage.

The light emitting element LD may be connected between an anode electrode AE and a cathode electrode CE. The anode electrode AE may be connected to the first power voltage node VDDN through the sub-pixel circuit SPC. For example, the anode electrode AE may be connected to the first power voltage node VDDN through one or more transistors in the sub-pixel circuit SPC. The cathode electrode CE may be connected to the second power voltage node VSSN. The light emitting element LD may emit light based on current flowing from the anode electrode AE to the cathode electrode CE.

The sub-pixel circuit SPC may be connected both to the i-th gate line GLi among the first to m-th gate lines GL1 to GLm of FIG. 1 and to the j-th data line DLj among the first to n-th data lines DL1 to DLn of FIG. 1. In response to a gate signal received through the i-th gate line GLi, the sub-pixel circuit SPC may control the light emitting element LD to emit light based on a data signal received through the j-th data line DLj. In embodiments, the sub-pixel circuit SPC may be further connected to the pixel control lines PXCL of FIG. 1. The sub-pixel circuit SPC may further control the light emitting element LD in response to pixel control signals received through the pixel control lines PXCL.

For these operations, the sub-pixel circuit SPC may include circuit elements, such as transistors and capacitors.

The transistors of the sub-pixel circuit SPC may include P-type transistors and/or N-type transistors. In embodiments, the transistors of the sub-pixel circuit SPC may include a metal oxide silicon field effect transistor (MOSFET). In embodiments, the transistors of the sub-pixel circuit SPC may include a material, sch as an amorphous silicon semiconductor, a monocrystalline silicon semiconductor, a polycrystalline silicon semiconductor, an oxide semiconductor, or the like.

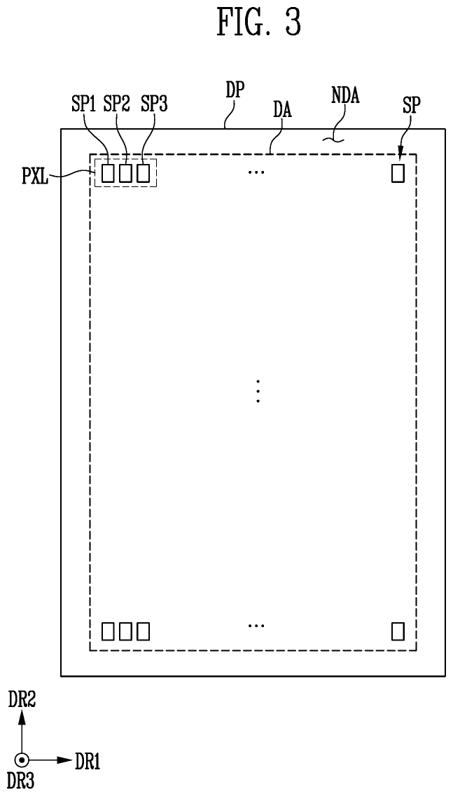

FIG. 3 is a schematic plan view illustrating an embodiment of a display panel of FIG. 1.

Referring to FIG. 3, the display panel DP may include a display area DA and a non-display area NDA. The display panel DP may display an image through the display area DA. The non-display area NDA may surround the display area DA.

The display panel DP may include sub-pixels SP in the display area DA. The sub-pixels SP may be arranged in a first direction DR1 and a second direction DR2, which intersects the first direction DR1. For example, the sub-pixels SP may be arranged in the form of a matrix in the first direction DR1 and the second direction DR2. As another example, the sub-pixels SP may be arranged in a zigzag form in the first direction DR1 and the second direction DR2. The arrangement of the sub-pixels SP may vary depending on embodiments. The first direction DR1 may correspond to a row direction, and the second direction DR2 may correspond to a column direction.

Two or more sub-pixels among the sub-pixels SP may form one pixel PXL. Although FIG. 3 illustrates the pixel PXL as including three sub-pixels SP1 to SP3, the embodiments are not limited to this configuration. For example, the pixel PXL may include two sub-pixels. For convenience of explanation, it is assumed hereinafter that the pixel PXL includes first to third sub-pixels SP1 to SP3.

Each of the first to third sub-pixels SP1 to SP3 may generate light in one of various colors, such as red, green, blue, cyan, magenta, or yellow. For clarity and concise description, it is assumed that the first sub-pixel SP1 may generate red light, the second sub-pixel SP2 may generate green light, and the third sub-pixel SP3 may generate blue light.

Each of the first to third sub-pixels SP1 to SP3 may include at least one light emitting element that generates light. In embodiments, the light emitting elements of the first to third sub-pixels SP1 to SP3 may generate light in the same color. For example, the light emitting elements of the first to third sub-pixels SP1 to SP3 may generate blue light. In other embodiments, the light emitting elements of the first to third sub-pixels SP1 to SP3 may generate light in different colors. For example, the light emitting elements of the first to third sub-pixels SP1 to SP3 may generate red, green, and blue light, respectively.

The display panel DP may be a self-emissive display panel, such as an LED display panel using a micro-scale or nano-scale light emitting diode as a light emitting element, or an organic light emitting display panel (OLED panel) using an organic light emitting diode as a light emitting element.

Components for controlling the sub-pixels SP may be disposed in the non-display area NDA. Lines connected to the sub-pixels SP, such as the first to m-th gate lines GL1 to GLm, the first to n-th data lines DL1 to DLn, the power lines PL, and the pixel control lines PXCL of FIG. 1, may be disposed in the non-display area NDA.

At least one of the gate driver 120, the data driver 130, the voltage generator 140, and the controller 150 of FIG. 1 may be disposed in the non-display area NDA of the display panel DP. In embodiments, the gate driver 120 may be disposed in the non-display area NDA. The data driver 130, the voltage generator 140, and the controller 150 may be implemented as the driver integrated circuit DIC of FIG. 1, that is separate from the display panel DP. The driver integrated circuit DIC may be connected to the lines disposed in the non-display area NDA. In other embodiments, the gate driver 120, along with the data driver 130, the voltage generator 140, and the controller 150, may be implemented as a single integrated circuit separate from the display panel DP.

In embodiments, the display area DA may have various shapes. The display area DA may include a closed-loop shape with linear and/or curved sides. For example, the display area DA may have shapes such as a polygon, a circle, a semicircle, or an ellipse.

In embodiments, the display panel DP may have a planar display surface. In embodiments, the display panel DP may have a display surface that is least partially rounded. In embodiments, the display panel DP is bendable, foldable, or rollable. The display panel DP and/or its substrate may include materials having flexible properties.

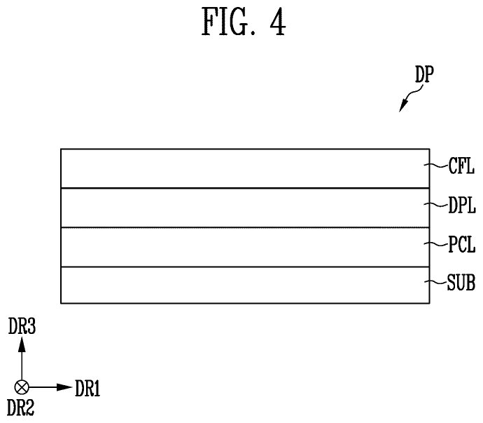

FIG. 4 is a schematic sectional view illustrating an embodiment of the display panel of FIG. 3.

Referring to FIG. 4, the display panel DP may include a substrate SUB, and a pixel circuit layer PCL, a display element layer DPL, and a color filter layer CFL, which are sequentially stacked on the substrate SUB in a third direction DR3 intersecting the first and second directions DR1 and DR2.

The substrate SUB may be made of insulating material such as glass or resin. For example, the substrate SUB may include a glass substrate. As another example, the substrate SUB may include a polyimide (PI) substrate. As another example, the substrate SUB may include a silicon wafer substrate formed through a semiconductor process.

In embodiments, the substrate SUB may be made of a material having flexibility, making it bendable or foldable, and may have a single-layer structure or a multilayer structure. For instance, the material having flexibility may include at least one of the following: polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, the embodiments are not limited to these examples.

The pixel circuit layer PCL may be disposed on the substrate SUB. The pixel circuit layer PCL may include insulating layers, along with semiconductor patterns and conductive patterns disposed between the insulating layers. The conductive patterns in the pixel circuit layer PCL may function as circuit elements, lines, or the like.

The circuit elements of the pixel circuit layer PCL may include the respective sub-pixel circuits SPC (refer to FIG. 2) of the sub-pixels SP shown in FIG. 3. The circuit elements of the pixel circuit layer PCL may be provided as transistors and one or more capacitors of the sub-pixel circuit SPC.

The lines of the pixel circuit layer PCL may include lines connected to the sub-pixels SP. The lines of the pixel circuit layer PCL may include various signal lines and/or voltage lines needed to drive the display element layer DPL.

The display element layer DPL may be disposed on the pixel circuit layer PCL. The display element layer DPL may include light emitting elements of the sub-pixels SP.

The color filter layer CFL, which includes color filters, may be disposed on the display element layer DPL. Each of the color filters may selectively transmit light of a specific wavelength (or specific color).

A window may be provided on the color filter layer CFL to protect an exposed surface (or upper surface) of the display panel DP. The window may protect the display panel DP from an external impact. The window may be coupled to the color filter layer CFL using an optically transparent adhesive (or bonding) agent. The window may have a multilayer structure, which includes a glass substrate, a plastic film, or a plastic substrate. The multilayer structure may be formed through a successive process or an adhesion process using an adhesive layer. The entirety or portion of the window may have flexibility.

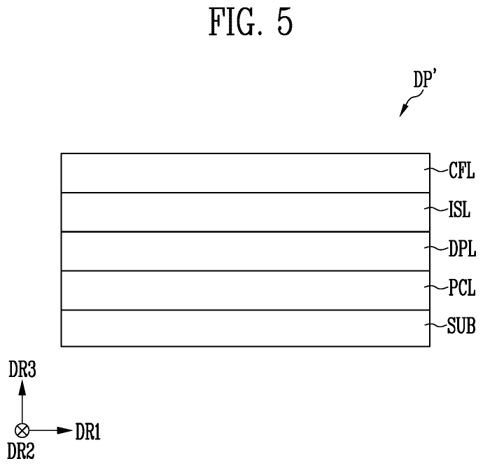

FIG. 5 is a schematic sectional view illustrating another embodiment of the display panel of FIG. 3.

Referring to FIG. 5, a display panel DP′ may include a substrate SUB, a pixel circuit layer PCL, a display element layer DPL, an input sensing layer ISL, and a color filter layer CFL. The substrate SUB, the pixel circuit layer PCL, the display element layer DPL, and the color filter layer CFL may be configured similarly to the substrate SUB, the pixel circuit layer PCL, the display element layer DPL, and the color filter layer CFL that have been described with reference to FIG. 4. Repetitive explanations will be omitted for brevity.

The input sensing layer ISL may sense a user input on an upper surface (or display surface) of the display panel DP′. The input sensing layer ISL may include components suitable for detecting an external object such as a user's hand, a pen, or the like. For example, the input sensing layer ISL may include touch electrodes.

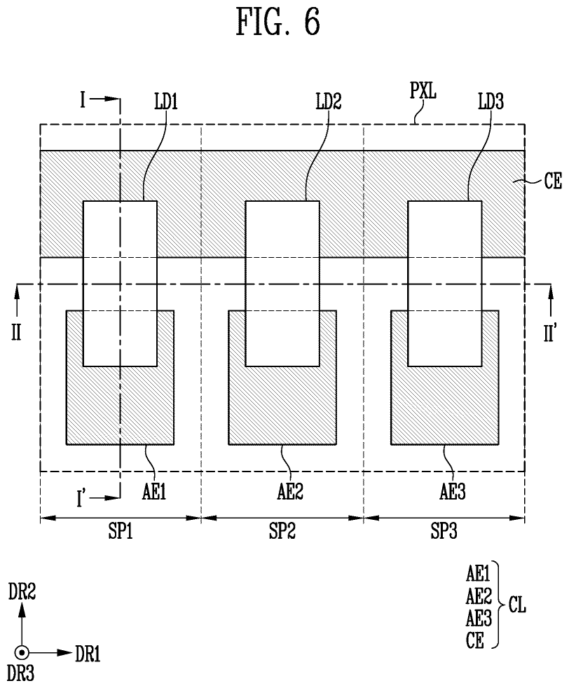

FIG. 6 is a schematic plan view illustrating an embodiment of a pixel PXL from FIG. 3.

Referring to FIG. 6, the pixel PXL may include first to third sub-pixels SP1 to SP3. The first to third sub-pixels SP1 to SP3 may be arranged in the first direction DR1. However, the arrangement of the pixel PXL is not limited to this and may vary depending on the embodiments. For example, the first to third sub-pixels SP1 to SP3 may be arranged in a zigzag pattern.

The display panel DP (refer to FIG. 3) may include an electrode layer CL. The electrode layer CL may form first to third anode electrodes AE1 to AE3 and a cathode electrode CE.

The first to third anode electrodes AE1 to AE3 may be disposed in the first to third sub-pixels SP1 to SP3, respectively. The first anode electrode AE1 may function as the anode electrode AE (refer to FIG. 2) connected to the sub-pixel circuit SPC (refer to FIG. 2) of the first sub-pixel SP1. The second anode electrode AE2 may function as the anode electrode AE connected to the sub-pixel circuit SPC of the second sub-pixel SP2. The third anode electrode AE3 may function as the anode electrode AE connected to the sub-pixel circuit SPC of the third sub-pixel SP3.

The cathode electrode CE may be spaced apart from the first to third anode electrodes AE1 to AE3. The cathode electrode CE may be disposed at the same height as the first to third anode electrodes AE1 to AE3. The cathode electrode CE may be spaced apart from the first to third anode electrodes AE1 to AE3 in the second direction DR2. In embodiments, the cathode electrode CE may extend in the first direction DR1 and may act as a common electrode for the pixel PXL and other pixels adjacent to the pixel PXL. Although not illustrated, in embodiments, the cathode electrode CE may extend in both the first direction DR1 and the second direction DR2, serving as a common electrode for all of the sub-pixels SP in FIG. 3. Thus, the cathode electrode CE may take various shapes.

First to third light emitting elements LD1 to LD3 may be disposed on the first to third anode electrodes AE1 to AE3 and the cathode electrode CE. The first light emitting element LD1 may be electrically connected to the first anode electrode AE1 and the cathode electrode CE. The first light emitting element LD1 may function as the light emitting element LD (refer to FIG. 2) connected to the sub-pixel circuit SPC of the first sub-pixel SP1. The second light emitting element LD2 may be electrically connected to the second anode electrode AE2 and the cathode electrode CE. The second light emitting element LD2 may function as a light emitting element LD connected to the sub-pixel circuit SPC of the second sub-pixel SP2. The third light emitting element LD3 may be electrically connected to the third anode electrode AE3 and the cathode electrode CE. The third light emitting element LD3 may function as a light emitting element LD connected to the sub-pixel circuit SPC of the third sub-pixel SP3.

The first light emitting element LD1, the second light emitting element LD2, and the third light emitting element LD3 may be inorganic light emitting diodes including inorganic light emitting material. However, the embodiments are not limited to this example, and organic light emitting diodes may be used, for example.

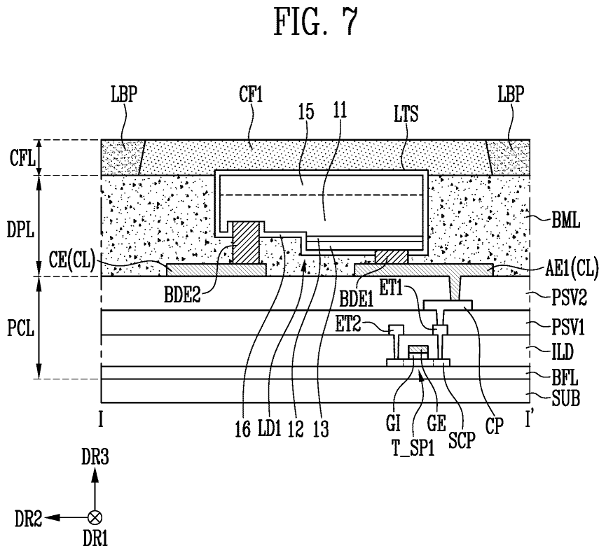

FIG. 7 is a schematic sectional view taken along line I-I′ of FIG. 6.

Referring to FIGS. 6 and 7, the pixel circuit layer PCL, the display element layer DPL, and the color filter layer CFL may be sequentially disposed on the substrate SUB.

The pixel circuit layer PCL may include insulating layers, semiconductor patterns, and conductive patterns that are stacked on the substrate SUB. The insulating layers may include a buffer layer BFL, one or more interlayer insulating layers ILD, and one or more passivation layers PSV1 and PSV2. The semiconductor patterns and the conductive patterns may be positioned between the insulating layers. The conductive patterns may include at least one material of copper (Cu), molybdenum (Mo), tungsten (W), aluminum-neodymium (AlNd), titanium (Ti), aluminum (Al), and silver (Ag).

As described with reference to FIG. 2, the sub-pixel circuit SPC (refer to FIG. 2) of each of the first to third sub-pixels SP1 to SP3 may include transistors and one or more capacitors. The semiconductor patterns and the conductive patterns included in the pixel circuit layer PCL may function as the transistors and the capacitors of the sub-pixel circuit SPC. Furthermore, the conductive patterns of the pixel circuit layer PCL may also function as lines, for example, the first to m-th gate lines GL1 to GLm, the first to n-th data lines DL1 to DLn, the power lines PL, and the pixel control lines PXCL of FIG. 1.

The buffer layer BFL may be disposed on a surface of the substrate SUB. The buffer layer BFL may prevent impurities from diffusing into the circuit elements and the lines that are included in the pixel circuit layer PCL. The buffer layer BFL may include an inorganic insulating layer including inorganic material. In embodiments, the buffer layer BFL may include at least one of silicon nitride (SiNₓ), silicon oxide (SiOₓ), silicon oxynitride (SiOₓN_{y}), and metal oxide such as aluminum oxide (AlOₓ). The buffer layer BFL may be provided in the form of a single layer or multiple layers. In case that the buffer layer BFL is provided a multilayer structure, the respective layers may be formed of the same or different materials.

In embodiments, one or more barrier layers may be disposed between the substrate SUB and the buffer layer BFL. Each of the barrier layers may include polyimide.

A transistor T_SP1 may be disposed on the buffer layer BFL. The transistor T_SP1 may be a transistor in the sub-pixel circuit SPC included in the first sub-pixel SP1. For example, the first transistor T_SP1 may be connected to the first anode electrode AE1 among the transistors of the sub-pixel circuit SPC.

The transistor T_SP1 may include a semiconductor pattern SCP, a gate electrode GE, a first terminal ET1, and a second terminal ET2. The first terminal ET1 may function as either a source electrode or a drain electrode, and the second terminal ET2 may be a remaining one of the source electrode and the drain electrode. For example, the first terminal ET1 may be a source electrode, and the second terminal ET2 may be a drain electrode.

The semiconductor pattern SCP may be disposed on the buffer layer BFL. The semiconductor pattern SCP may include a first contact area that contacts the first terminal ET1, and a second contact area that contacts the second terminal ET2. An area between the first contact area and the second contact area may function as a channel area. The channel area may overlap the gate electrode GE of the transistor T_SP1. The channel area may be an undoped semiconductor pattern, and may function as an intrinsic semiconductor. Each of the first contact area and the second contact area may be a semiconductor pattern doped with an impurity. For example, a p-type impurity may be used as the impurity, but the embodiments are not limited thereto.

The semiconductor pattern SCP may include various types of semiconductors, for example, an amorphous silicon semiconductor, a monocrystalline silicon semiconductor, a polycrystalline silicon semiconductor, a low temperature polysilicon semiconductor, and an oxide semiconductor.

The interlayer insulating layers ILD, that are sequentially stacked, may be disposed on the semiconductor pattern SCP. The interlayer insulating layers ILD may be formed of inorganic insulating layers including inorganic material. For example, each of the interlayer insulating layers ILD may include at least one of silicon nitride (SiNₓ), silicon oxide (SiOₓ), silicon oxynitride (SiOₓN_{y}), and metal oxide such as aluminum oxide (AlOₓ). However, the material of the interlayer insulating layers ILD is not limited to these examples. For example, the interlayer insulating layer ILD may include an organic insulating layer including organic material.

The interlayer insulating layers ILD may electrically separate the conductive patterns and/or semiconductor patterns that are disposed between the interlayer insulating layers ILD from each other. For example, the interlayer insulating layers ILD may include a gate insulating layer GI disposed on the semiconductor pattern SCP. The gate insulating layer GI may be disposed between the semiconductor pattern SCP and the gate electrode GE such that the gate electrode GE is spaced apart from the semiconductor pattern SCP. In embodiments, the gate insulating layer GI may be disposed on the overall surfaces of the semiconductor pattern SCP and the buffer layer BFL, thereby covering the semiconductor pattern SCP and the buffer layer BFL. As the number of layers forming the conductive patterns and/or the semiconductor patterns increases, the number of interlayer insulating layers ILD may increase.

The gate electrode GE may be disposed on the gate insulating layer GI. The gate electrode GE may overlap the channel area of the semiconductor pattern SCP. In embodiments, the gate electrode GE may be formed as a single layer that includes at least one material selected from copper (Cu), molybdenum (Mo), tungsten (W), aluminum-neodymium (AlNd), titanium (Ti), aluminum (Al), silver (Ag), and a combination thereof. In embodiments, the gate electrode GE may be formed as a multilayer structure that includes at least one low-resistance material selected from molybdenum (Mo), titanium (Ti), aluminum (Al), silver (Ag), and a combination thereof.

The first and second terminals ET1 and ET2 may be disposed on the interlayer insulating layers ILD. The first and second terminals ET1 and ET2 may contact the semiconductor pattern SCP through contact holes that pass through the interlayer insulating layers ILD. The first and second terminals ET1 and ET2 may contact the first and second contact areas of the semiconductor pattern SCP, respectively. Each of the first and second terminals ET1 and ET2 may include at least one material selected from copper (Cu), molybdenum (Mo), tungsten (W), aluminum-neodymium (AlNd), titanium (Ti), aluminum (Al), silver (Ag), and a combination thereof.

Although the first and second terminals ET1 and ET2 are illustrated as separate electrodes electrically connected to the semiconductor pattern SCP, the embodiments are not limited to this configuration. In embodiments, the first terminal ET1 may be a first contact area adjacent to one side of the channel area of the semiconductor pattern SCP, and the second terminal ET2 may be a second contact area adjacent to the other side of the channel area. The first terminal ET1 may be electrically connected to the light emitting element LD through a connector, such as a bridge electrode, disposed on at least one of the interlayer insulating layers ILD.

In embodiments, the transistor T_SP1 may be formed of a low-temperature polysilicon transistor. However, embodiments are not limited to this example. For example, the transistor T_SP1 may be formed of an oxide semiconductor transistor. In embodiments, the sub-pixel circuit of the first sub-pixel SP1 may include different types of transistors. For example, the transistor T_SP1 may be a low-temperature polysilicon transistor. The other transistors of the first sub-pixel SP1 may be oxide semiconductor transistors. An oxide semiconductor of the corresponding oxide semiconductor transistor may be disposed on the interlayer insulating layers ILD, rather than on an insulating layer on which the semiconductor pattern SCP of the transistor T_SP1 is disposed.

Although the embodiments describe the transistor T_SP1 as having a top gate structure as an example, the embodiments are not limited to this configuration. For example, the transistor T_SP1 may be a transistor having a bottom gate structure. The structure of the transistor T_SP1 may vary in different ways.

At least some of the various lines for the display panel DP and/or the display device DD may be further disposed on the interlayer insulating layers ILD.

The first passivation layer PSV1 may be disposed on the interlayer insulating layers ILD and the first and second terminals ET1 and ET2. The passivation layer may also be referred to as a protective layer or a via layer. The first passivation layer PSV1 may protect components disposed below it and provide an even upper surface.

A connection pattern CP may be disposed on the first passivation layer PSV1. The connection pattern CP may pass through the first passivation layer PSV1 and be connected to the first terminal ET1 of the transistor T_SP1. The connection pattern CP may include at least one material selected from copper (Cu), molybdenum (Mo), tungsten (W), aluminum-neodymium (AlNd), titanium (Ti), aluminum (Al), silver (Ag), and a combination thereof.

At least some of the various lines for the display panel DP and/or the display device DD may be further disposed on the first passivation layer PSV1.

The second passivation layer PSV2 may be disposed on the connection pattern CP and the first passivation layer PSV1. The second passivation layer PSV2 may protect components disposed below it and provide an even upper surface.

Each of the first and second passivation layers PSV1 and PSV2 may include an inorganic insulating layer including inorganic material, and/or an organic insulating layer including organic material. The inorganic insulating layer may include, for example, at least one of silicon oxide (SiOₓ), silicon nitride (SiNₓ), silicon oxynitride (SiOₓN_{y}), and metal oxide such as aluminum oxide (AlOₓ). The organic insulating layer may include, for example, at least one of acrylic resin, epoxy resin, phenol resin, polyamide resin, polyimide rein, unsaturated polyester resin, poly-phenylen ether resin, poly-phenylene sulfide resin, and benzocyclobutene resin.

The first and second passivation layers PSV1 and PSV2, and the interlayer insulating layer ILD may include a same material, but the embodiments are not limited thereto. Each of the first and second passivation layers PSV1 and PSV2 may be provided as a single-layer structure, or may be provided as a multilayer structure.

The display element layer DPL may be disposed on the second passivation layer PSV2. The display element layer DPL may include the electrode layer CL, a light blocking layer BML, and the first light emitting element LD1.

The first anode electrode AE1 and the cathode electrode CE may be disposed on the pixel circuit layer PCL.

The first anode electrode AE1 may be electrically connected to a connection pattern CP through a contact hole passing through the second passivation layer PSV2. As such, the first anode electrode AE1 may be electrically connected to the first transistor T_SP1.

The cathode electrode CE may be spaced apart from the first anode electrode AE1 in the first direction DR1. The cathode electrode CE may be electrically connected to the second power voltage node VSSN of FIG. 2. Accordingly, a second power voltage applied to the second power voltage node VSSN may be transmitted to the cathode electrode CE.

The first light emitting element LD1 may be electrically connected to the first anode electrode AE1. The first light emitting element LD1 may also be electrically connected to the cathode electrode CE. The first light emitting element LD1 may be bonded and coupled to both the first anode electrode AE1 and the cathode electrode CE.

In an embodiment, a reflective electrode may be disposed between the first anode electrode AE1 and the first light emitting element LD1. In an embodiment, a reflective electrode may be disposed between the cathode electrode CE and the first light emitting element LD1. The reflective electrode may include conductive materials suitable for reflecting light, thereby enhancing the light output efficiency of the first light emitting element LD1. For example, the reflective layer may include at least one material selected from aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more of these materials.

The first light emitting element LD1 may include a first semiconductor layer 11, an active layer 12, a second semiconductor layer 13, and an auxiliary layer 15. The first light emitting element LD1 may include an emission stack where the auxiliary layer 15, the first semiconductor layer 11, the active layer 12, and the second semiconductor layer 13 are sequentially stacked.

The first light emitting element LD1 may include first and second bonding electrodes BDE1 and BDE2, both oriented in the same direction (e.g., in a direction opposite to the third direction DR3). The first bonding electrode BDE1 may be connected to the second semiconductor layer 13. The second bonding electrode BDE2 may be connected to the first semiconductor layer 11, exposed by etching the second semiconductor layer 13 and the active layer 12. The first light emitting element LD1 may be a flip-chip-type light emitting element.

The first semiconductor layer 11 may provide electrons to the active layer 12. The first semiconductor layer 11 may include, for example, at least one n-type semiconductor layer. For example, the first semiconductor layer 11 may include a semiconductor material, such as gallium nitride (GaN), aluminum gallium nitride (AlGaN), indium gallium nitride (InGaN), aluminum nitride (AlN), and indium nitride (InN), and may be an n-type semiconductor layer doped with a first conductive dopant (or n-type dopant) such as silicon (Si), germanium (Ge), or tin (Sn). However, the material for forming the first semiconductor layer 11 is not limited to these examples, and various other materials may be used to form the first semiconductor layer 11. In an embodiment, the first semiconductor layer 11 may include gallium nitride (GaN) semiconductor material doped with a first conductive dopant (or an n-type dopant). In an embodiment, the first semiconductor layer 11, along with the auxiliary layer 15, may form an n-type semiconductor layer.

The active layer 12 may be disposed on the first semiconductor layer 11, and may be an area where electrons and holes are recombined. As electrons and holes recombine in the active layer 12, they transition to a low energy level, thereby generating light having a corresponding wavelength. The active layer 12 may have a single or multi-quantum well structure. In case that the active layer 12 has a multi-quantum well structure, units each including a barrier layer, a strain-reinforcing layer, and a well layer may be repeatedly stacked to form the active layer 12. However, embodiments of the active layer 12 are not limited to this example.

The second semiconductor layer 13 may be disposed on the active layer 12 and may provide holes to the active layer 12. The second semiconductor layer 13 may be of a different type than the first semiconductor layer 11. For example, the second semiconductor layer 13 may include at least one p-type semiconductor layer. For example, the second semiconductor layer 13 may include at least one semiconductor material selected from gallium nitride (GaN), aluminum gallium nitride (AlGaN), indium gallium nitride (InGaN), aluminum nitride (AlN), and indium nitride (InN), and may be a p-type semiconductor layer doped with a second conductive dopant (or p-type dopant) such as magnesium (Mg), zinc (Zn), calcium (Ca), strontium (Sr), barium (Ba), or the like. However, the material for forming the second semiconductor layer 13 is not limited to these examples, and various other materials may be used to form the second semiconductor layer 13. In an embodiment, the second semiconductor layer 13 may include gallium nitride (GaN) semiconductor material doped with a second conductive dopant (or a p-type dopant).

The auxiliary layer 15 may include undoped gallium nitride (GaN) semiconductor material and may form an n-type semiconductor layer together with the first semiconductor layer 11.

The first bonding electrode BDE1 may be electrically connected to the second semiconductor layer 13. The second bonding electrode BDE2 may be electrically connected to the first semiconductor layer 11. The first and second bonding electrodes BDE1 and BDE2 may include eutectic metal.

The first light emitting element LD1 may further include an insulating layer 16 provided to cover an outer circumferential surface of the emission stack. The insulating layer 16 may prevent the active layer 12 from short-circuiting due to contact with conductive materials other than the first and second semiconductor layers 11 and 13. The insulating layer 16 may include transparent insulating material. The insulating layer 16 may expose the lower surfaces of the first and second bonding electrodes BDE1 and BDE2.

The lower surface of the first bonding electrode BDE1 may be electrically connected to the first anode electrode AE1. The lower surface of the second bonding electrode BDE2 may be electrically connected to the cathode electrode CE.

The light blocking layer BML may cover the electrode layer CL and the second passivation layer PSV2. An upper surface of the light blocking layer BML may be lower than an upper surface of the first light emitting element LD1. For example, a space between the color filter layer CFL and the second passivation layer PSV2 may be filled with the light blocking layer BML. For example, the light blocking layer BML may be disposed under the first light emitting element LD1. An area between the first light emitting element LD1 and the electrode layer CL, as well as the second passivation layer PSV2, may be filled with the light blocking layer BML.

The light blocking layer BML may include light blocking material to prevent light mixing between adjacent sub-pixels. In embodiments, the light blocking layer BML may include organic material. For example, the light blocking layer BML may include organic insulating material such as acryl resin, epoxy resin, phenol resin, polyamide resin, polyimide resin, or the like.

The pixel circuit layer PCL and the display element layer DPL of the first sub-pixel SP1 have been described above. Each of the second and third sub-pixels SP2 and SP3, as shown in FIG. 6, may be configured similarly to the first sub-pixel SP1 unless otherwise described.

The color filter layer CFL may be disposed on the display element layer DPL. The color filter layer CFL may include a first color filter CF1 and light blocking patterns LBP. The first color filter CF1 may overlap the first light emitting element LD1. The first color filter CF1 may allow light in a desired wavelength range to selectively pass through. In the case where the first sub-pixel SP1 is a red sub-pixel, the first color filter CF1 may include a red color filter. The light blocking patterns LBP may include various kinds of light blocking materials.

In an embodiment, a passivation layer may be disposed on the light blocking layer BML. The passivation layer may protect components below it and provide an even upper surface. The passivation layer and either of the first and second passivation layers PSV1 and PSV2 may include a same material.

In an embodiment, a capping layer may be disposed on the light blocking layer BML. The capping layer may protect components such as the first light emitting element LD1 from external water, moisture, or the like. For example, the capping layer may include at least one material selected from silicon nitride (SiNₓ), silicon oxide (SiOₓ), silicon oxynitride (SiOₓN_{y}), and metal oxide such as aluminum oxide (AlOₓ). However, the material of the capping layer may not be limited to these examples.

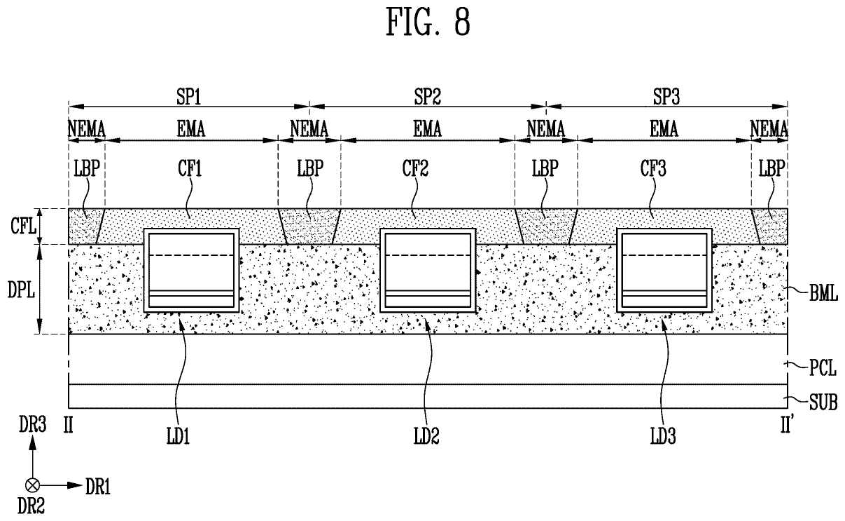

FIG. 8 is a schematic sectional view taken along line II-II′ of FIG. 6.

Referring to FIGS. 6 and 8, the pixel circuit layer PCL, the display element layer DPL, and the color filter layer CFL may be sequentially provided on the substrate SUB.

The pixel circuit layer PCL and the display element layer DPL may be described similarly to those in FIG. 7. Sub-pixel circuits respectively corresponding to the first, second, and third sub-pixels SP1, SP2, and SP3 may be provided in the pixel circuit layer PCL. The first, second, and third light emitting elements LD1, LD2, and LD3 respectively corresponding to the first, second, and third sub-pixels SP1, SP2, and SP3 may be provided in the display element layer DPL. Hereinafter, repetitive explanations will be omitted.

The color filter layer CFL may be provided on the display element layer DPL. The color filter layer CFL may be described similarly to those in FIG. 7. Repetitive explanations will be omitted.

In an embodiment, the first light emitting element LD1 may emit red light, the second light emitting element LD2 may emit green light, and the third light emitting element LD3 may emit blue light.

In an embodiment, the first, second, and third light emitting elements LD1, LD2, and LD3 may emit light in a single color. For example, the display panel DP (refer to FIG. 3) may display various colors through the first, second, and third color filters CF1, CF2, and CF3. For example, the display panel DP may further include a component for converting the single color to other colors.

Each of the first to third color filters CF1 to CF3 may allow light in a desired wavelength range to selectively pass through. In the case where the first sub-pixel SP1 is a red sub-pixel, the first color filter CF1 may include a red color filter. In the case where the second sub-pixel SP2 is a green sub-pixel, the second color filter CF2 may include a green color filter. In the case where the third sub-pixel SP3 is a blue sub-pixel, the third color filter CF3 may include a blue color filter.

The light blocking patterns LBP may be disposed between the first, second, and third color filters CF1, CF2, and CF3. It can be understood that the emission area (or light output area) EMA and the non-emission area NEMA for each of the first, second, and third sub-pixels SP1, SP2, and SP3 are defined by the light blocking patterns LBP. An area overlapping the light blocking patterns LBP may correspond to the non-emission area NEMA. An area that does not overlap the light blocking patterns LBP may correspond to the emission area EMA.

In embodiments, the light blocking patterns LBP may include various kinds of light blocking materials. In embodiments, each of the light blocking patterns LBP may take the form of a multilayer structure where at least two of the color filters CF1, CF2, and CF3 overlap. For example, each of the light blocking patterns LBP may be formed by overlapping the first, second, and third color filters CF1, CF2, and CF3. As another example, a light blocking pattern between the first and second color filters CF1 and CF2 among the light blocking patterns LBP may be formed of a multilayer structure in which the first and second color filters CF1 and CF2 overlap. A light blocking pattern between the second and third color filters CF2 and CF3 among the light blocking patterns LBP may be formed by overlapping the second and third color filters CF2 and CF3. A light blocking pattern between the first color filter CF1 and a third color filter CF3 of a neighboring pixel may also be formed of a multilayer structure where the first and third color filters CF1 and CF3 overlap. As such, each of the first, second, and third color filters CF1, CF2, and CF3 may extend into the non-emission area NEMA, thus forming the light blocking patterns LBP.

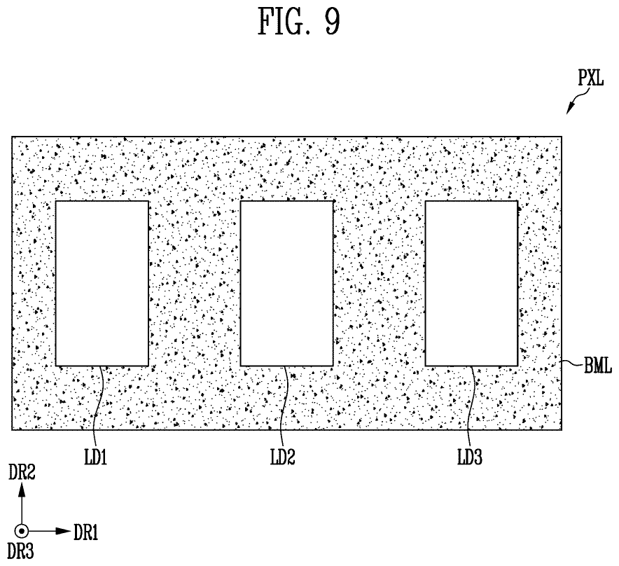

FIG. 9 is a schematic plan view illustrating an embodiment of the light emitting elements and the light blocking layer in a pixel of FIG. 3.

Referring to FIG. 9, the light blocking layer BML may enclose (or surround) the first, second, and third light emitting elements LD1, LD2, and LD3 in a plan view.

During a process of fabricating the display panel DP (refer to FIG. 3), the first, second, and third light emitting elements LD1, LD2, and LD3 may be misaligned and bonded at incorrect positions instead of their intended positions. However, since the light blocking layer BML may enclose (or surround) the first, second, and third light emitting elements LD1, LD2, and LD3, these elements are not covered with the light blocking layer BML in case of misalignment of the first, second, and third light emitting elements LD1, LD2, and LD3. Consequently, the light output efficiency of the first to third light emitting elements LD1, LD2, and LD3 may be enhanced.

For example, in the case where there is no space between the light blocking layer BML and the first, second, and third light emitting elements LD1, LD2, and LD3, light may be prevented from entering the space and being reflected in the space. As a result, the proportion of reflected external light in the light emitted from the display panel DP may be reduced, and the light output efficiency of the first, second, and third light emitting elements LD1, LD2, and LD3 may be enhanced.

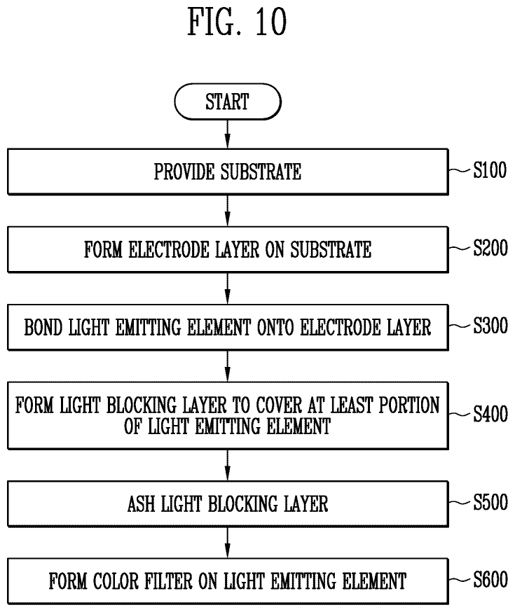

FIG. 10 is a schematic flowchart illustrating a method of fabricating the display device in accordance with embodiments.

Referring to FIG. 10, the method of fabricating the display device may include step S100 of providing a substrate, step S200 of forming an electrode layer on the substrate, step S300 of bonding a light emitting element to the electrode layer, step S400 of forming a light blocking layer to cover at least a portion of the light emitting element, step S500 of ashing the light blocking layer, and step S600 of forming a color filter on the light emitting element.

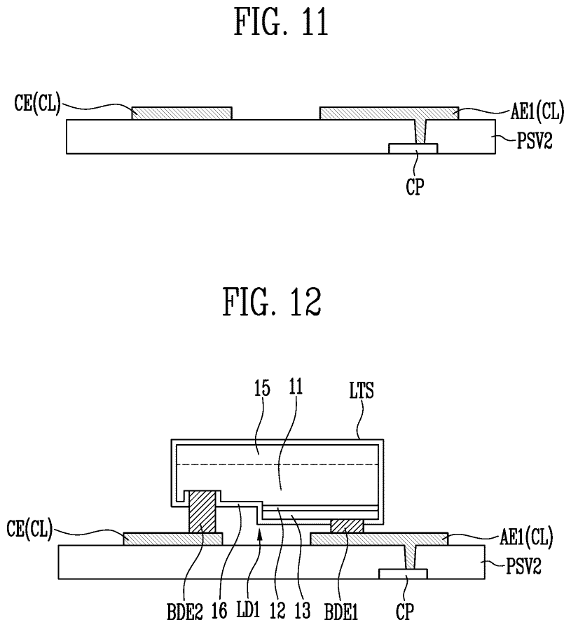

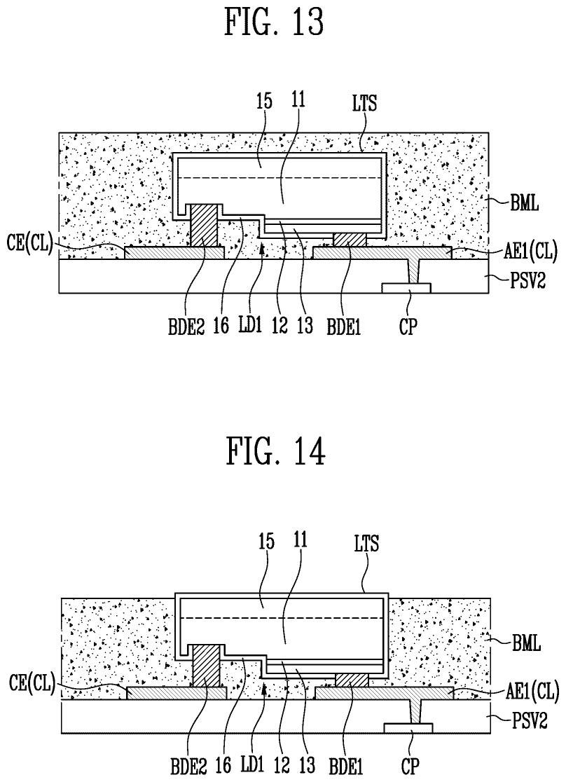

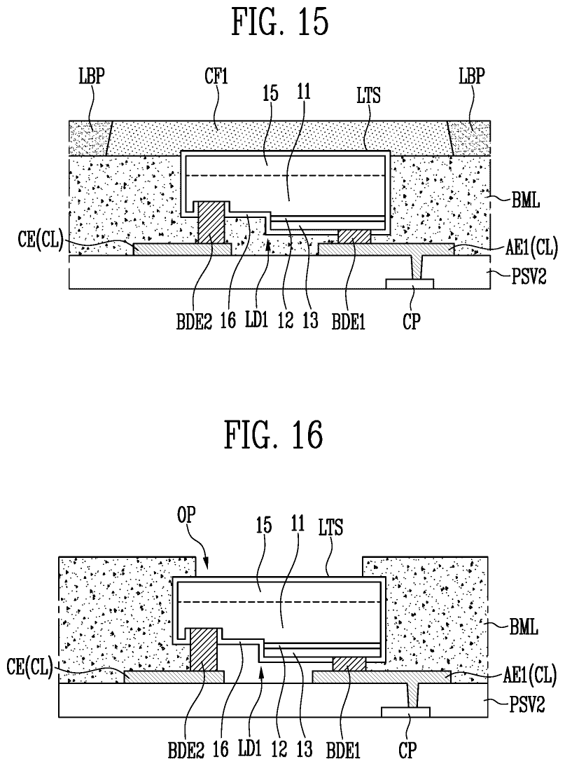

FIG. 11 is a schematic diagram illustrating steps S100 and S200 of FIG. 10. FIG. 12 is a schematic diagram illustrating step S300 of FIG. 10. FIG. 13 is a schematic diagram illustrating step S400 of FIG. 10. FIG. 14 is a schematic diagram illustrating step S500 of FIG. 10. FIG. 15 is a schematic diagram illustrating step S600 of FIG. 10.

The components in FIGS. 11 to 15 are the same as the components of the display device described with reference to FIGS. 6 to 9; therefore, redundant explanations will be omitted.

Referring to FIGS. 7 and 11, the second passivation layer PSV2 may be formed over the substrate SUB. The electrode layer CL may be formed on the second passivation layer PSV2. The electrode layer CL may include the first anode electrode AE1 and the cathode electrode CE.

Referring to FIGS. 7 and 12, the first light emitting element LD1 may be bonded to the electrode layer CL. For example, the first bonding electrode BDE1 may be bonded to the first anode electrode AE1, and the second bonding electrode BDE2 may be bonded to the cathode electrode CE.

Referring to FIGS. 7 and 13, the light blocking layer BML may cover the entire first light emitting element LD1. For example, materials constituting the light blocking layer BML may be applied to the overall area of the substrate SUB.

Referring to FIGS. 7 and 14, the light blocking layer BML may be ashed. For example, the light blocking layer BML may be ashed such that an upper surface of the light blocking layer BML is lower than an upper surface LTS of the first light emitting element LD1. As such, after the light blocking layer BML is formed, the first light emitting element LD1 may be exposed by ashing the light blocking layer BML, preventing the first light emitting element LD1 from being misaligned or covered with the light blocking layer BML.

Referring to FIGS. 7 and 15, the color filter layer CFL may be formed over the first light emitting element LD1 and the light blocking layer BML. For example, the first color filter CF1 may be formed on the first light emitting element LD1.

Although FIGS. 11 to 15 illustrate only the first sub-pixel SP1, each of the second and third sub-pixels SP2 and SP3 may be configured similarly to the first sub-pixel SP1. Repetitive explanations will be omitted.

FIGS. 16 to 18 are schematic diagrams describing another embodiment of steps S400 to S600 of FIG. 10.

The components in FIGS. 16 to 18 are the same as those of the display device described with reference to FIGS. 6 to 9. Redundant explanations will be omitted.

Referring to FIGS. 7 and 16, the light blocking layer BML may cover a portion of the first light emitting element LD1. For example, the light blocking layer BML may include an opening OP through which a portion of the first light emitting element LD1 is exposed. For example, the materials constituting the light blocking layer BML may be patterned and applied to the substrate SUB.

FIG. 16 illustrates an example where the light blocking layer BML is not disposed under the first light emitting element LD1. The light blocking layer BML may flow into the space under the first light emitting element LD1 during the fabrication process.

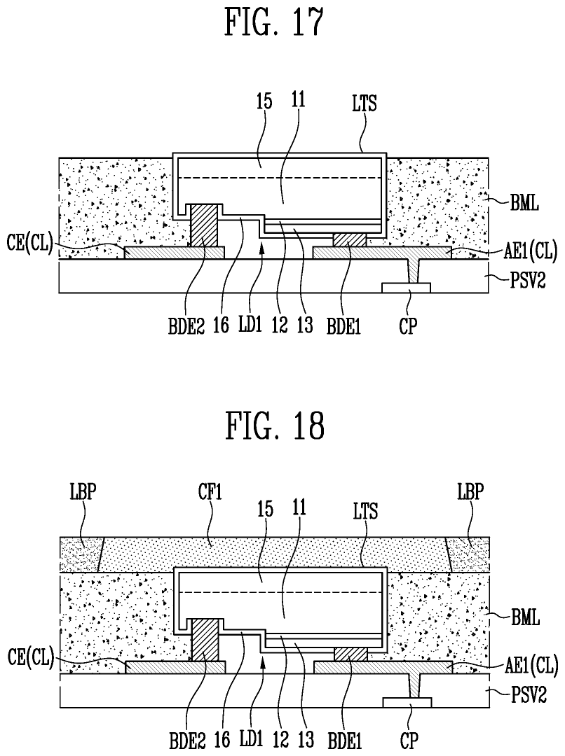

Referring to FIGS. 7 and 17, the light blocking layer BML may be ashed. For example, the light blocking layer BML may be ashed such that its upper surface is lower than the upper surface LTS of the first light emitting element LD1. After forming the light blocking layer BML, the first light emitting element LD1 may be exposed by ashing the light blocking layer BML, preventing the first light emitting element LD1 from being misaligned or covered by the light blocking layer BML.

Referring to FIGS. 7 and 18, the color filter layer CFL may be formed over the first light emitting element LD1 and the light blocking layer BML. For example, the first color filter CF1 may be formed on the first light emitting element LD1.

Although FIGS. 16 to 18 illustrate only the first sub-pixel SP1, each of the second and third sub-pixels SP2 and SP3 may be configured similarly to the first sub-pixel SP1. Repetitive explanations will be omitted.

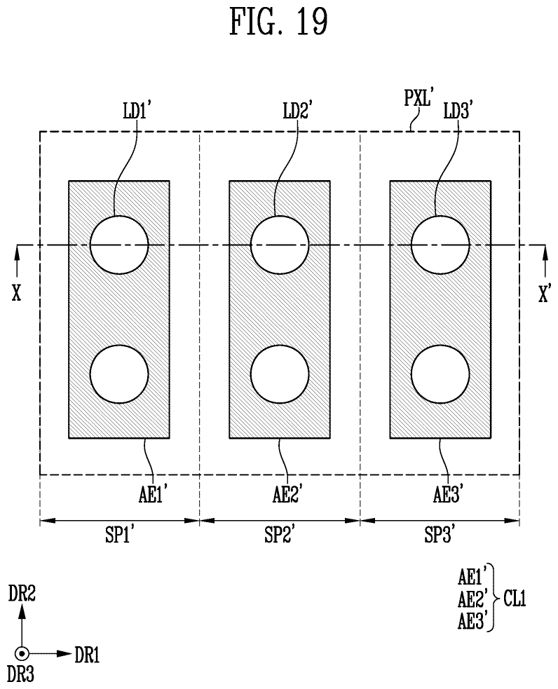

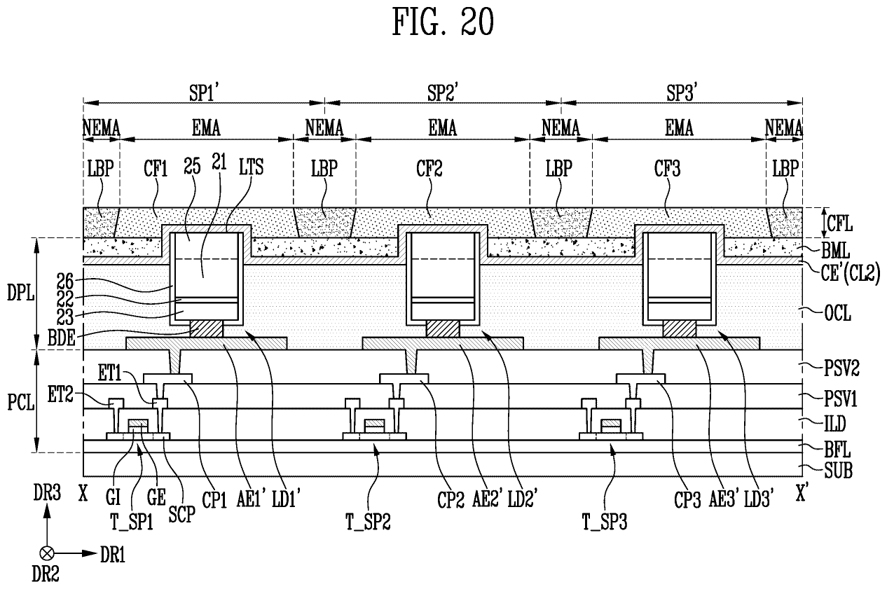

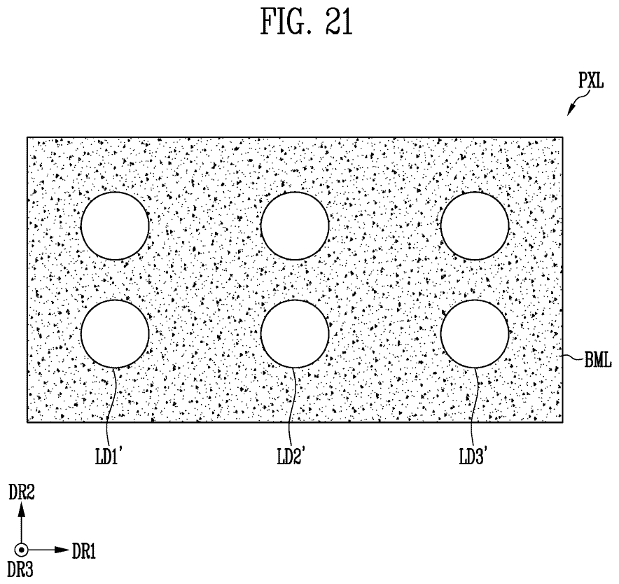

FIG. 19 is a schematic plan view illustrating another embodiment of a pixel of the display device in accordance with embodiments. FIG. 20 is a schematic sectional view taken along line X-X′ of FIG. 19. FIG. 21 is a schematic plan view illustrating another embodiment of the light emitting elements and the light blocking layer in a pixel of FIG. 3.

The configuration of the display device in these embodiments is substantially the same as the display device shown in FIGS. 6 to 9, except for a display element layer DPL. Therefore, identical or similar components are denoted by the same reference numerals and symbols, and redundant explanations will be omitted.

Referring to FIG. 19, a pixel PXL′ may include first to third sub-pixels SP1′ to SP3′. The first to third sub-pixels SP1′ to SP3′ may be arranged in the first direction DR1. However, the arrangement of the pixel PXL′ is not limited to this and may vary depending on the embodiments. For example, the first to third sub-pixels SP1′ to SP3′ may be arranged in a zigzag pattern.

First to third anode electrodes AE1′ to AE3′ may be disposed in the first to third sub-pixels SP1′ to SP3′, respectively. The first anode electrode AE1′ may function as the anode electrode AE (refer to FIG. 2) included in the sub-pixel circuit SPC (refer to FIG. 2) of the first sub-pixel SP1′. The second anode electrode AE2′ may function as an anode electrode AE included in the sub-pixel circuit SPC of the second sub-pixel SP2′. The third anode electrode AE3′ may function as an anode electrode AE included in the sub-pixel circuit SPC of the third sub-pixel SP3′.

One or more first light emitting elements LD1′, one or more second light emitting elements LD2′, and one or more third light emitting elements LD3′ may be disposed on the first to third anode electrodes AE1′ to AE3′, respectively. The first light emitting elements LD1′ may be connected to the first anode electrode AE1′. The second light emitting elements LD2′ may be connected to the second anode electrode AE2′. The third light emitting elements LD3′ may be connected to the third anode electrode AE3′. In the case where multiple light emitting elements are provided in each sub-pixel, each anode electrode may have a shape extending in a specific direction, e.g., the second direction DR2, and the light emitting elements connected thereto may be arranged in the same direction.

The first light emitting elements LD1′ may correspond to the light emitting element LD in FIG. 2, included in the first sub-pixel SP1′. The second light emitting elements LD2′ may correspond to the light emitting element LD in FIG. 2, included in the second sub-pixel SP2′. The third light emitting elements LD3′ may correspond to the light emitting element LD in FIG. 2, included in the third sub-pixel SP3′. In the case where multiple light emitting elements are provided in each sub-pixel, the light emitting elements may be connected in parallel between the anode electrode and the cathode electrode and function as the light emitting element LD of FIG. 2.

The first light emitting elements LD1′, the second light emitting elements LD2′, and the third light emitting elements LD3′ may be inorganic light emitting diodes that include inorganic light emitting material. However, the embodiments are not limited to this example. For example, organic light emitting diodes may also be used.

Referring to FIGS. 19 and 20, the pixel circuit layer PCL, the display element layer DPL, and the color filter layer CFL may be sequentially disposed on the substrate SUB.

The display element layer DPL may be disposed on the second passivation layer PSV2. The display element layer DPL may include a first electrode layer CL1, the first to third light emitting elements LD1′ to LD3′, an overcoat layer OCL, a light blocking layer BML, and a second electrode layer CL2.

The first electrode layer CL1 may form the first to third anode electrodes AE1′ to AE3′. The second electrode layer CL2 may form a cathode electrode CE′.

On the pixel circuit layer PCL, the first to third anode electrodes AE1′ to AE3′ may be disposed in the first to third sub-pixels SP1′ to SP3′, respectively.

The first anode electrode AE1′ may be electrically connected to a first connection pattern CP1 through a contact hole passing through the second passivation layer PSV2. The second anode electrode AE2′ may be electrically connected to a second connection pattern CP2 through another contact hole passing through the second passivation layer PSV2. The third anode electrode AE3′ may be electrically connected to a third connection pattern CP3 through another contact hole passing through the second passivation layer PSV2. As such, the first to third anode electrodes AE1′ to AE3′ may be electrically connected to the first to third transistors T_SP1 to T_SP3, respectively.

The first to third light emitting elements LD1′ to LD3′ may be disposed on the first to third anode electrodes AE1′ to AE3′, respectively. The first to third light emitting elements LD1′ to LD3′ may be bonded and coupled to the first to third anode electrodes AE1′ to AE3′, respectively.

The first light emitting element LD1′ may include a bonding electrode BDE, a first semiconductor layer 21, an active layer 22, a second semiconductor layer 23, and an auxiliary layer 25. The first light emitting element LD1′ may be implemented as a vertical emission stack, where the bonding electrode BDE, the second semiconductor layer 23, the active layer 22, the first semiconductor layer 21, and the auxiliary layer 25 are sequentially stacked in the third direction DR3.

The first semiconductor layer 21 may provide electrons. The first semiconductor layer 21 may include, for example, at least one n-type semiconductor layer. For example, the first semiconductor layer 21 may include a semiconductor material selected from gallium nitride (GaN), aluminum gallium nitride (AlGaN), indium gallium nitride (InGaN), aluminum nitride (AlN), and indium nitride (InN). The first semiconductor layer 21 may be an n-type semiconductor layer doped with a first conductive dopant (or n-type dopant) such as silicon (Si), germanium (Ge), or tin (Sn). However, the material used for the first semiconductor layer 21 is not limited to this example, and various other materials may be used to form the first semiconductor layer 21. In an embodiment, the first semiconductor layer 21 may include gallium nitride (GaN) semiconductor material doped with a first conductive dopant (or an n-type dopant). In an embodiment, the first semiconductor layer 21, together with the auxiliary layer 25, may form an n-type semiconductor layer.

The active layer 22 may be disposed on the first semiconductor layer 21 and may be an area where electrons and holes recombine. As electrons and holes recombine in the active layer 22, they transition to a low energy level, generating light having a corresponding wavelength. The active layer 22 may have either a single or multi-quantum well structure. In case that the active layer 22 has a multi-quantum well structure, units each including a barrier layer, a strain-reinforcing layer, and a well layer may be repeatedly stacked to form the active layer 22. However, embodiments of the active layer 22 are not limited to this example.

The second semiconductor layer 23 may be disposed on the active layer 22 and may provide holes to the active layer 22. The second semiconductor layer 23 may be of a different type than the first semiconductor layer 21. For example, the second semiconductor layer 23 may include at least one p-type semiconductor layer. For example, the second semiconductor layer 23 may include at least one semiconductor material selected from gallium nitride (GaN), aluminum gallium nitride (AlGaN), indium gallium nitride (InGaN), aluminum nitride (AlN), and indium nitride (InN), and may be a p-type semiconductor layer doped with a second conductive dopant (or p-type dopant) such as magnesium (Mg), zinc (Zn), calcium (Ca), strontium (Sr), barium (Ba), or the like. However, the material used to form the second semiconductor layer 23 is not limited to this example, and various other materials may be used to form the second semiconductor layer 23. In an embodiment, the second semiconductor layer 23 may include gallium nitride (GaN) semiconductor material doped with a second conductive dopant (or a p-type dopant).

The bonding electrode BDE may be electrically connected to the second semiconductor layer 23. The bonding electrode BDE may include eutectic metal.

The auxiliary layer 25 may include undoped gallium nitride (GaN) semiconductor material and may form an n-type semiconductor layer along with the first semiconductor layer 21.

The first light emitting element LD1′ may further include an insulating layer 26, which covers an outer circumferential surface of the vertical emission stack. The insulating layer 26 may prevent the active layer 22 from short-circuiting due to contact with conductive materials other than the first and second semiconductor layers 21 and 23. The insulating layer 26 may include transparent insulating material. The insulating layer 26 may expose a lower surface of the bonding electrode BDE, which is opposite to the second semiconductor layer 23. Furthermore, the insulating layer 26 may expose an upper surface of the auxiliary layer 25, which contacts the cathode electrode CE′.

The lower surface of the bonding electrode BDE may be connected to the first anode electrode AE1′. The upper surface of the auxiliary layer 25 may be connected to the cathode electrode CE′. As a result, the first light emitting element LD1′ may be electrically connected between the first anode electrode AE1′ and the cathode electrode CE′.

In embodiments, a reflective electrode may be disposed between the bonding electrode BDE and the second semiconductor layer 23. Light emitted from the first light emitting element LD1′ may be efficiently outputted toward the color filter layer CFL. The reflective electrode may be formed from conductive material having a desired reflectivity. The conductive material may include opaque metal. For example, the opaque metal may include metal such as silver (Ag), magnesium (Mg), aluminum (Al), platinum (Pt), palladium (Pd), gold (Au), nickel (Ni), neodymium (Nd), iridium (Ir), chrome (Cr), titanium (Ti), or an alloy thereof. However, the material of the reflective electrode is not limited to this example.

Each of the second and third light emitting elements LD2′ and LD3′ may be configured similarly to the first light emitting element LD1′. Repetitive explanations will be omitted.

The overcoat layer OCL may be disposed on the second passivation layer PSV2. An area between the second passivation layer PSV2 and the second electrode layer CL2 may be filled with the overcoat layer OCL. The overcoat layer OCL may secure the first to third light emitting elements LD1′ to LD3′, which are bonded to the first to third anode electrodes AE1′ to AE3′, in place to prevent the first to third light emitting elements LD1′ to LD3′ from moving. The overcoat layer OCL may protect the components below it from foreign substances such as dust and water. For example, the overcoat layer OCL may include at least one of an inorganic insulating layer and an organic insulating layer. For example, the overcoat layer OCL may include epoxy, but embodiments are not limited to this.

In embodiments, the overcoat layer OCL may not cover an upper surface LTS of each of the first to third light emitting elements LD1′ to LD3′. The first to third light emitting elements LD1′ to LD3′ may protrude into the color filter layer CFL, allowing light emitted from the first to third light emitting elements LD1′ to LD3′ to reach the color filter layer CFL at a relatively high rate.

The cathode electrode CE′ may be disposed on the first to third light emitting elements LD1′ to LD3′. The cathode electrode CE′ may cover the overall areas of the first to third light emitting elements LD1′ to LD3′ as well as the overcoat layer OCL. The cathode electrode CE′ may contact the auxiliary layer 25 of each of the first to third light emitting elements LD1′ to LD3′. The cathode electrode CE′ may be electrically connected to the second power voltage node VSSN of FIG. 2. A second power voltage applied to the second power voltage node VSSN may be transmitted to the first to third light emitting elements LD1′ to LD3′ through the cathode electrode CE′.

The cathode electrode CE′ may be substantially transparent or translucent to meet a certain light transmittance requirement. In embodiments, the cathode electrodes CE′ may include at least one transparent conductive material, such as indium tin oxide (ITO), indium zinc oxide (IZO), zinc oxide (ZnO), indium gallium zinc oxide (IGZO), indium tin zinc oxide (ITZO), and a combination thereof. However, the material used for the cathode electrode CE′ is not limited to these examples.

In an embodiment, a capping layer may be disposed on the cathode electrode CE′. The capping layer may protect components disposed under the capping layer, such as the cathode electrode CE′ and the first to third light emitting elements LD1′ to LD3′, from external water, moisture, or the like. The capping layer may include at least one material selected from silicon nitride (SiNₓ), silicon oxide (SiOₓ), silicon oxynitride (SiOₓN_{y}), and a metal oxide such as aluminum oxide (AlOₓ). However, the material of the capping layer is not limited to these examples.

The light blocking layer BML may be formed on a portion of the second electrode layer CL2. For example, the light blocking layer BML may be formed on a portion of the second electrode layer CL2 that does not overlap the first to third light emitting elements LD1′ to LD3′. The upper surface of the light blocking layer BML may be lower than an upper surface of a portion of the second electrode layer CL2 that overlaps the first to third light emitting elements LD1′ to LD3′.

The light blocking layer BML may include a light blocking material to prevent light mixing between adjacent sub-pixels. In embodiments, the light blocking layer BML may include organic material. For example, the light blocking layer BML may include an organic insulating material such as acryl resin, epoxy resin, phenol resin, polyamide resin, polyimide resin, or the like.

Referring to FIG. 21, the light blocking layer BML may enclose (or surround) the first to third light emitting elements LD1′ to LD3′ in a schematic plan view.

During a fabrication process of the display panel DP (refer to FIG. 3), the first to third light emitting elements LD1′ to LD3′ may be misaligned and bonded in incorrect positions instead of intended positions thereof. However, since the light blocking layer BML may enclose (or surround) the first to third light emitting elements LD1′ to LD3′, the first to third light emitting elements LD1′ to LD3′ are not covered by the light blocking layer BML, even if the first to third light emitting elements LD1′ to LD3′ are misaligned. Consequently, the light output efficiency of the first to third light emitting elements LD1′ to LD3′ may be enhanced.

Furthermore, since there is no space between the light blocking layer BML and the first to third light emitting elements LD1′ to LD3′, light may be prevented from entering the space and being reflected. As a result, the proportion of reflected external light among light emitted from the display panel DP may be reduced, and the light output efficiency of the first to third light emitting elements LD1′ to LD3′ may be enhanced.

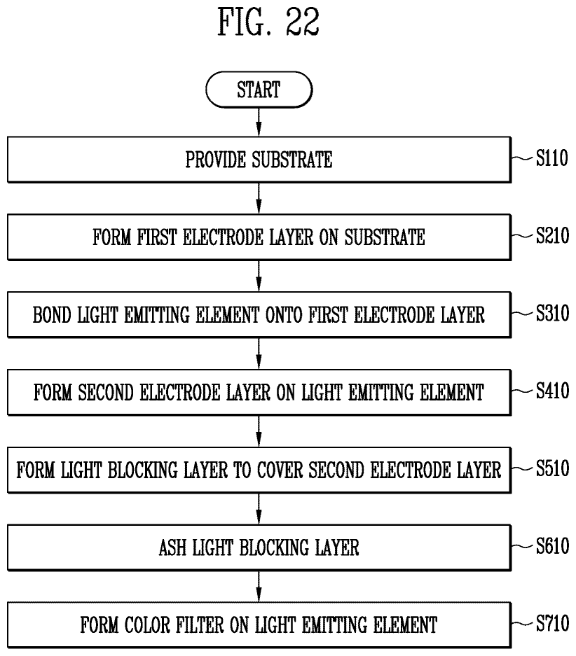

FIG. 22 is a flowchart illustrating a method of fabricating the display device in accordance with embodiments.

Referring to FIG. 22, the method of fabricating the display device may include the following steps: step S110 of providing a substrate, step S210 of forming a first electrode layer on the substrate, step S310 of bonding a light emitting element to the first electrode layer, step S410 forming a second electrode layer on the light emitting element, step S510 of forming a light blocking layer to cover the second electrode layer, step S610 of ashing the light blocking layer, and step S710 of forming a color filter on the light emitting element.

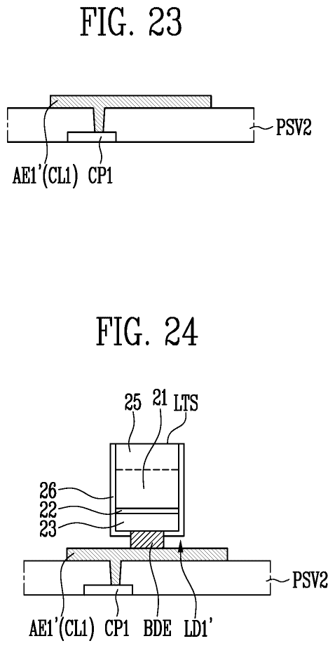

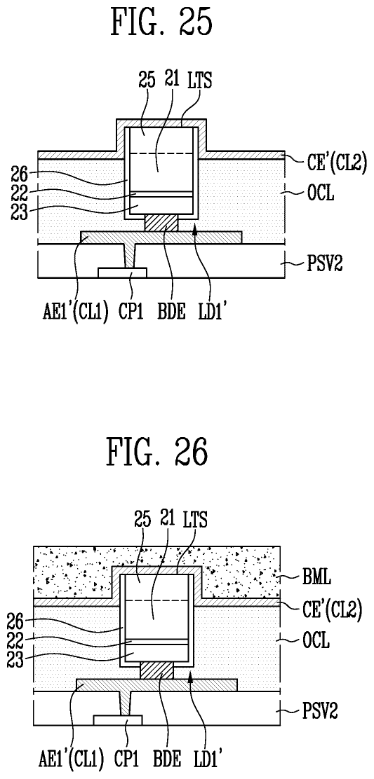

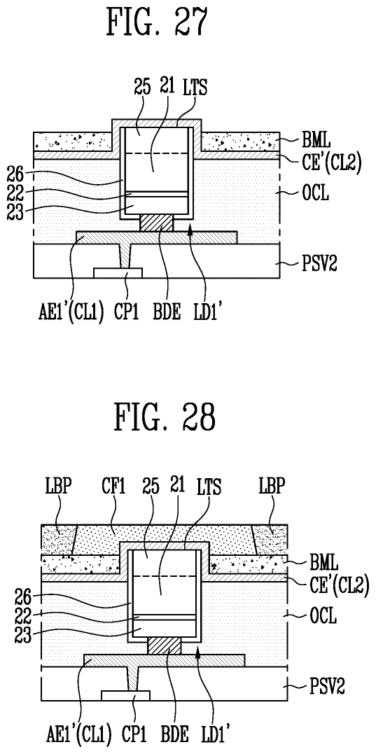

FIG. 23 is a schematic diagram for describing steps S110 and S210 of FIG. 22. FIG. 24 is a schematic diagram for describing step S310 of FIG. 22. FIG. 25 is a schematic diagram for describing step S410 of FIG. 22. FIG. 26 is a schematic diagram for describing step S510 of FIG. 22. FIG. 27 is a schematic diagram for describing step S610 of FIG. 22. FIG. 28 is a schematic diagram for describing step S710 of FIG. 22.

The components in FIGS. 23 to 27 are the same as those described in the display device with reference to FIGS. 19 to 21; therefore, redundant explanations will be omitted.

Referring to FIGS. 20 and 23, the second passivation layer PSV2 may be formed over the substrate SUB. The first electrode layer CL1 may be formed on the second passivation layer PSV2. The first electrode layer CL1 may include the first anode electrode AE1′.

Referring to FIGS. 20 and 24, the first light emitting element LD1′ may be bonded to the first electrode layer CL1. For example, the bonding electrode BDE may be bonded to the first anode electrode AE1′.

Referring to FIGS. 20 and 25, the overcoat layer OCL may be formed on the first electrode layer CL1 and the second passivation layer PSV2. The second electrode layer CL2 may cover the overcoat layer OCL and the first light emitting element LD1′.

Referring to FIGS. 20 and 26, the light blocking layer BML may cover at least a portion of the first light emitting element LD1′. In this embodiment, an example is described where the light blocking layer BML covers the entire first light emitting element LD1′, but the disclosure is not limited to this. For example, the light blocking layer BML may cover a portion of the first light emitting element LD1′.

Referring to FIGS. 20 and 27, the light blocking layer BML may be ashed. For example, the light blocking layer BML may be ashed such that its upper surface is lower than an upper surface of a portion of the second electrode layer CL2 that overlaps the light emitting elements, including the first light emitting element LD1′. As a result, after the light blocking layer BML is formed, the cathode electrode CE′ may be exposed by ashing the light blocking layer BML, preventing the first light emitting element LD1′ from being misaligned or covered by the light blocking layer BML.

Referring to FIGS. 20 and 28, the color filter layer CFL may be formed on the first light emitting element LD1′ and the light blocking layer BML. For example, the first color filter CF1 may be formed on the first light emitting element LD1′.

Although FIGS. 23 to 28 illustrate only the first sub-pixel SP1′, each of the second and third sub-pixels SP2′ and SP3′ may be configured similarly to the first sub-pixel SP1′. Repetitive explanations will be omitted.

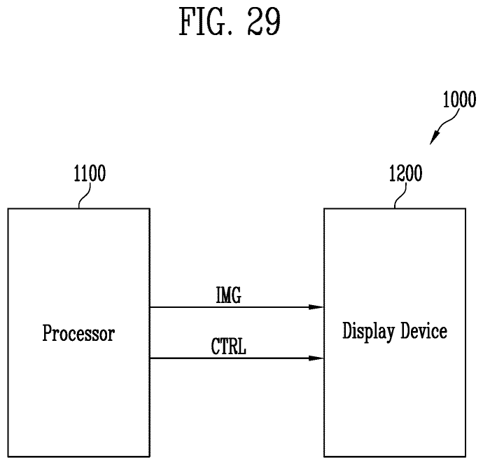

FIG. 29 is a schematic block diagram illustrating an embodiment of a display system 1000.

Referring to FIG. 29, the display system 1000 may include a processor 1100 and a display device 1200.

The processor 1100 may perform various tasks and operations. In embodiments, the processor 1100 may include an application processor, a graphic processor, a microprocessor, a central processing unit (CPU), and so on. The processor 1100 may be connected to other components of the display system 1000 through a bus system to control the components.

The processor 1100 may transmit image data IMG and a control signal CTRL to the display device 1200. The display device 1200 may display an image based on the image data IMG and the control signal CTRL. The display device 1200 may be configured similarly to the display device DD described with reference to FIG. 1. The image data IMG and the control signal CTRL may correspond to the input image data IMG and the control signal CTRL of FIG. 1, respectively.

The display system 1000 may include computing systems that provide an image display function, such as a smart watch, a mobile phone, a smart phone, a portable computer, a tablet personal computer (tablet PC), a watch phone, an automotive display, smart glasses, a portable multimedia player (PMP), a navigation system, or an ultra-mobile personal computer (UMPC). Furthermore, the display system 1000 may include at least one of a head-mounted display (HMD), a virtual reality (VR) device, a mixed reality (MR) device, and an augmented reality (AR) device.

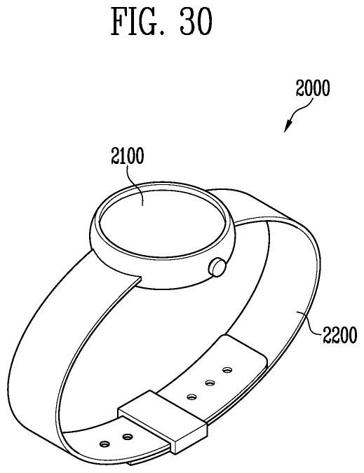

FIGS. 30 to 33 are schematic perspective views illustrating application examples of the display system 1000 of FIG. 29.

Referring to FIG. 30, the display system 1000 of FIG. 29 may be applied to a smart watch 2000, which includes a display component 2100 and a strap 2200.

The smart watch 2000 may be a wearable electronic device. For example, the smart watch 2000 may have a structure in which the strap 2200 may be mounted on the wrist of the user. The display system 1000 and/or the display device 1200 may be applied to the display component 2100, so that image data, including time information, can be provided to the user.

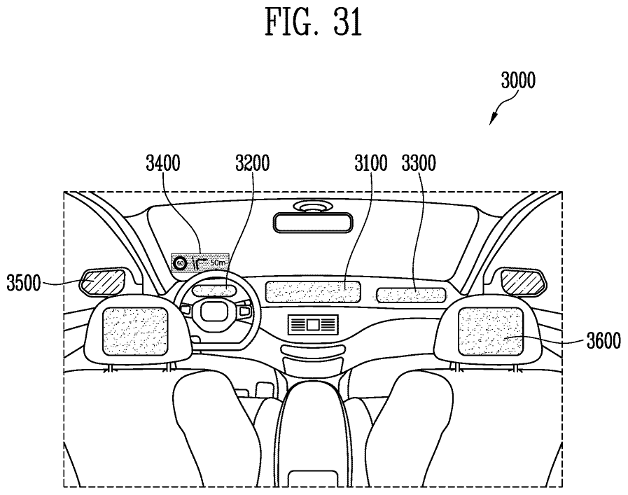

Referring to FIG. 31, the display system 1000 of FIG. 29 may be applied to an automotive display system 3000. The automotive display system 3000 may include a computing system provided inside and/or outside a vehicle to provide image data.

For example, the display system 1000 and/or the display device 1200 may be applied to at least any of the following: an infotainment panel 3100, a cluster 3200, a co-driver display 3300, a head-up display 3400, a side mirror display 3500, and a rear seat display 3600, all of which may be provided in the vehicle.

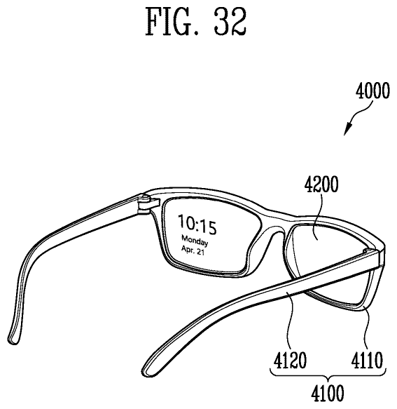

Referring to FIG. 32, the display system 1000 of FIG. 29 may be applied to smart glasses 4000. The smart glasses 4000 may be a wearable electronic device that can be worn on the head of the user. For example, the smart glasses 4000 may be a wearable device for augmented reality.

The smart glasses 4000 may include a frame 4100 and a lens component 4200. The frame 4100 may include a housing 4110 which supports the lens component 4200, and a leg component 4120 enabling the user to wear the smart glasses. The leg component 4120 may be connected to the housing 4110 by a hinge, allowing it to be folded or unfolded with respect to the housing 4110.

The frame 4100 may be equipped with a battery, a touch pad, a microphone, a camera, and the like. Furthermore, the frame 4100 may include a projector that outputs light, and a processor that controls a light signal and the like.

The lens component 4200 may include an optical component that transmits or reflects light. For example, the lens component 4200 may include glass, transparent synthetic resin, and the like.

To enable the user to perceive visual information, the lens component 4200 may reflect images based on an optical signal transmitted from the projector in the frame 4100 by a rear surface of the lens component 4200 (e.g., a surface facing the user's eyes). For example, the user may perceive visual information such as time and date displayed on the lens component 4200. Here, the projector and/or the lens component 4200 may function as a display device, and the display device 1200 may be applied to the projector and/or the lens component 4200.

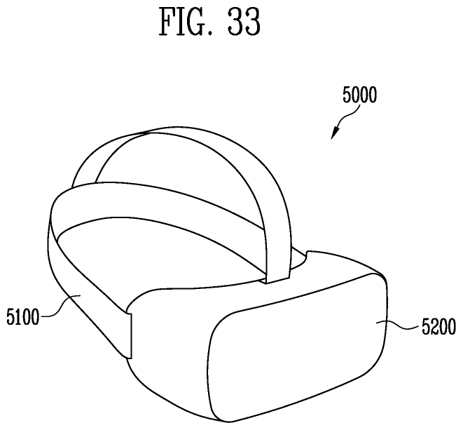

Referring to FIG. 33, the display system 1000 of FIG. 29 may be applied to a head-mounted display device 5000.

The head-mounted display device 5000 may be a wearable electronic device worn on the user's head. For example, the head-mounted display device 5000 may be a wearable device for virtual reality or mixed reality.

The head-mounted display 5000 may include a head-mounted band 5100 and a display device reception casing 5200. The head-mounted band 5100 may be connected to the display device reception casing 5200. The head-mounted band 5100 may include a horizontal band and/or a vertical band to fasten the head-mounted display 5000 to the user's head. The horizontal band may enclose (or surround) the sides of the user's head, and the vertical band may enclose (or surround) the top of the user's head. However, the embodiments are not limited to this configuration. For example, the head-mounted band 5100 may be implemented in the form of eyeglass frames, a helmet, and so on.

The display device reception casing 5200 may house the display system 1000 and/or the display device 1200.

In a method of fabricating a display device in accordance with embodiments, a light blocking layer may cover at least a portion of a light emitting element, and the light blocking layer may then be ashed. This process may prevent the light emitting element from being misaligned or covered by the light blocking layer, thereby enhancing the light output efficiency of the light emitting element.

In the method of fabricating the display device in accordance with embodiments, the light blocking layer may cover at least a portion of the light emitting element, followed by ashing. As a result, in a plan view, the space between the light emitting element and the light blocking layer may be minimized, reducing the proportion of reflected external light among the light emitted from the display panel. Accordingly, the light output efficiency of the light emitting element may be increased.

The effects of the disclosure are not limited to those described above, and various modifications are possible without departing from the spirit and scope of the disclosure.

The disclosure may be applied to a display device and an electronic device including the display device. For example, the disclosure may be applied to digital TVs, 3D TVs, cellular phones, smartphones, tablet computers, VR devices, PCs, home appliances, laptop computers, PDAs, portable media players (PMPs), digital cameras, music players, portable game consoles, navigation devices, and so on.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A method of fabricating a display device, the method comprising:
providing a substrate;
forming an electrode layer on the substrate;
bonding a light emitting element to the electrode layer;
forming a light blocking layer to cover at least a portion of the light emitting element;
ashing the light blocking layer; and
forming a color filter on the light emitting element.

2. The method of claim 1, wherein the light blocking layer covers an entirety of the light emitting element.

3. The method of claim 1, wherein the light blocking layer includes an opening through which a portion of the light emitting element is exposed.

4. The method of claim 1, wherein the light blocking layer is ashed such that an upper surface of the light blocking layer is lower than an upper surface of the light emitting element.

5. The method of claim 1, wherein
the electrode layer includes a first electrode and a second electrode that are electrically connected to the light emitting element, and
the first electrode and the second electrode are spaced apart from each other.

6. The method of claim 1, wherein the light blocking layer surrounds the light emitting element.

7. A method of fabricating a display device, the method comprising:
providing a substrate;
forming a first electrode layer on the substrate;
bonding a light emitting element to the first electrode layer;
forming a second electrode layer on the light emitting element;
forming a light blocking layer to cover the second electrode layer;
ashing the light blocking layer; and
forming a color filter on the light emitting element.

8. The method of claim 7, further comprising:
forming an overcoat layer on the first electrode layer, wherein
the second electrode layer covers the overcoat layer and the light emitting element.

9. The method of claim 7, wherein the light blocking layer is ashed such that an upper surface of the light blocking layer is lower than an upper surface of a portion of the second electrode layer that overlaps the light emitting element.

10. The method of claim 7, wherein the light blocking layer surrounds the light emitting element.

11. A display device, comprising:
a substrate;
an insulating layer disposed on the substrate;
an electrode layer disposed on the insulating layer;
a light emitting element disposed on the electrode layer;
a light blocking layer disposed on the electrode layer; and
a color filter disposed on the light emitting element, wherein
an upper surface of the light blocking layer is lower than an upper surface of the light emitting element.

12. The display device of claim 11, wherein
the electrode layer includes a first electrode and a second electrode that are electrically connected to the light emitting element, and
the first electrode and the second electrode are spaced apart from each other.

13. The display device of claim 11, wherein the light blocking layer is disposed under the light emitting element.

14. The display device of claim 11, wherein the light blocking layer surrounds the light emitting element.
